(19) United States
(12) Patent Application Publication
(10) Pub. No.: US 2009/0302503 A1
(43) Pub. Date: Dec. 10, 2009

(54) Coating Method

(75) Inventors: Jari Ruuttu, Billnas (FI); Reijo Lappalainen, Hiltulanlahti (FI); Vesa Myllymäki, Helsinki (FI); Lasse Pulli, Helsinki (FI); Juha Mäkitalo, Tammisaari (FI)

Correspondence Address: BIRCH STEWART KOLASCH & BIRCH, PO BOX 747, FALLS CHURCH, VA, 22040-0747, US

(73) Assignee: Picodeon LTD OY, Helsinki (FI)

(21) Appl. No.: 12/224,298

(22) PCT Filed: Feb. 23, 2007
(86) PCT No.: PCT/FI2007/000049

§ 371 Date: Mar. 12, 2009

(30) Foreign Application Priority Data
Feb. 23, 2006 (FI) 2006178

(51) Int. Cl. B29C 35/08; C23C 14/02

(52) U.S. Cl. 264/400; 118/620

(57) ABSTRACT

The subject of the invention is a coating method based on laser ablation where the distance between the substrate and the target being ablated is exceptionally small. The short distance allows coating the substrate even in industrial scale preferably also under a low-vacuum or even non-vacuum atmosphere. The invention is preferable in conjunction with the optimal coating of all large-size objects or objects with varying shapes.

### FIELD OF THE INVENTION

The subject of this invention is a coating method based on laser ablation where the distance between the substrate and the target being ablated is exceptionally small. The short distance allows coating the substrate even in industrial scale preferably also under a low-vacuum or even non-vacuum pressure.

### STATE OF THE ART

Considerable progress has been made in laser technology in recent years, and it is currently possible to produce semiconductor fibre-based laser systems, operating at a tolerable efficiency, that can be used for cold ablation, for example. Such lasers intended for cold working include picosecond lasers and femtosecond lasers. In the case of picosecond lasers, for example, the term cold working range refers to pulse durations of 100 picoseconds or less. Besides having different pulse durations, picosecond lasers differ from femtosecond lasers with respect to their repetition rate; the latest picosecond lasers have repetition rates in the region of 1-4 MHz while femtosecond lasers can only achieve repetition rates in the kHz range. At best, cold ablation allows vaporising material so that when vaporized (ablated) material no heat transference to the actual vaporizable material occur; in other words, only the material ablated by each pulse is subjected to the pulse energy.

The competitor of the completely fibre-based, diode-pumped semiconductor laser is the lamp-pumped laser source where the laser beam is first directed into a fibre and from there further to the point being worked. According to information available to the applicant on the priority date, these fibre-based laser systems are the only method currently available for laser ablation-based production in industrial scale.

The fibres used in present fibre lasers and the resulting low radiation power pose limitations to the range of materials that can be vaporised. Aluminium can as such be vaporized using a moderate pulse power while less readily vaporised materials, such as copper, tungsten, etc. require considerably higher pulse powers.

Another problem with the state of the art, is the scanning width of the laser beam. The method generally used has been linear scanning using a mirror film scanner; one can think that this theoretically allows a nominal scanning line width of some 70 mm, but in practice, the scanning width can problematically be limited to as little as 30 mm which means that the edges of the scanned area may be of uneven quality and/or different from the areas in the middle. Such small scanning widths also mean that the use of currently available laser equipment for industrial-scale coating applications of large, wide objects is economically or technically unfeasible.

The effective powers of pulse laser equipment intended for cold ablation and known at the time of priority date of the current application were, as far as the applicant is aware, limited to some 10 W in ablation. In this case, the repetition rate could be limited to a laser pulse rate of 4 MHz. If attempts are made to further increase the pulse rate, the scanners according to prior art will cause a significant part of the laser beam pulses to be uncontrollably directed not only to the wall structures of the laser equipment but also to ablated material in plasma form. This has the net effect of degrading the quality of surface formed of the ablated material and slowing down the rate at which it is produced, as well as the effect that the flux of radiation hitting the target varies too much which may be evident in the structure of the plasma formed and result in an uneven coating surface. The problems are amplified as the size of the plume of plasma material to be formed increases.

In arrangements according to prior art, problems are also caused by a change of focus of the laser beam during ablation in relation to the material being vaporised which will naturally immediately alter the quality of plasma as the pulse energy density on the surface of the material is (usually) decreased, resulting in incomplete vaporisation/formation of plasma. This results in low-energy plasma and unnecessarily large numbers of fragments/particles, as well as in a change in surface morphology, poor coating adhesion and/or change of coating thickness.

The significant developments in laser technology during recent years have produced tools for use in high-power laser systems, based on semiconductor fibres and therefore supporting the development of methods based on cold ablation.

However, the fibres of conventional fibre lasers prevent high-power use where pulse-form laser radiation of sufficient net power is conveyed to the worked area through an optical fibre. Applying the required power level to the worked area would cause such power losses due to absorption in the optical fibre that conventional fibre materials could not withstand them. One reason for deploying fibre technology to convey the laser radiation from the source to the target has been the fact that even the conveyance of a single beam through open air constitutes a moderate hazard for workers in an industrial environment, and it is technically very challenging if not impossible in a large-scale operation.

At the time of the priority date of the current application, purely fibre-based, diode-pumped semiconductor lasers were competing with lamp-pumped lasers, and in both types, the laser beam was first directed to the fibre and from there to the focus in the worked area. These fibre laser systems are the only ones suitable for industrial-scale laser ablation applications.

The currently available fibres in fibre lasers, as well as the resulting limitations of low radiation power, restrict the use of fibre materials for vaporising/ablating target materials. It is possible to vaporise/ablate aluminium using low-energy pulses while less readily vaporised/ablated materials such as copper, tungsten, etc. require considerably higher pulse power. The same applies to situations where the aim is to produce new compounds using the same prior art. Examples that warrant a mention include producing diamond directly from carbon or aluminium oxide directly from aluminium and oxygen through an appropriate gaseous phase reaction under post-ablation conditions.

On the other hand, one of the most significant obstacles to progress in this field appears to be the ability of fibre to withstand high-power laser pulses without breaking or causing a deterioration in the quality of the laser beam.

By using new cold ablation techniques, the quality and production capacity problems associated with coatings, thin-film production as well as cutting/scoring/engraving etc. have been approached by concentrating on increasing the laser power and reducing the size of the spot where the laser beam hits the target surface. However, much of the power was wasted on noise. The quality and production capacity problems remained unsolved even though some laser manufacturers succeeded in solving problems related to the laser power. Representative samples of both coatings/thin films and cutting/scoring/engraving etc. have only been possible to produce at low repetition rates, small scanning widths and long working times which as such are useless for industrial-scale applications. This is particularly true for large objects.

Due to the energy content of the pulse, the problem is amplified when the pulse power is increased while simultaneously shortening the pulse duration. Significant problems are encountered even using nanosecond pulse lasers even though they are not suitable as such for cold ablation techniques.

Shortening the pulse duration to the femtosecond or attosecond range makes the problem almost insurmountable. For example, in a picosecond laser system with a pulse duration of 10-15 ps, the pulse energy must be 5 μJ for a 10-30 μm spot when the total power of the laser is 100 W and the repetition rate is 20 MHz. Fibres capable of withstanding such pulse powers were not available on the priority date of the current application, as far as the author is aware.

The shorter the pulse, the more energy per time unit has to be fed through the cross-section of the fibre. In the above conditions for pulse duration and laser power, the amplitude level of an individual pulse may correspond to a power of some 400 kW. Manufacturing fibres that would withstand even 200 kW and permit pulses of 15 ps duration to pass through without a distortion from the optimal pulse shape was, according to the best knowledge of the author, not possible before the priority date of the current application.

If the objective is to avoid limiting the possibilities for producing plasma from any available material, one must be able to freely select the pulse power, for example in the range of 200 kW to 80 MW. The problems associated with the limitations of current fibre lasers are not attributable to fibres alone, but also to connecting separate diode-pumped lasers to each other using optical connectors when aiming at a certain total power. Such combined beams have been directed to the working point in a single fibre using conventional techniques.

Consequently, the optical connectors should be capable of withstanding at least the same power as the fibre itself when a transfer route is deployed for transferring the high-power pulses to the working point. Even with conventional power levels, suitable optical connectors are extremely expensive to manufacture and their operation is somewhat unreliable. They also wear out during use and must be replaced at certain intervals.

The production speed is directly proportional to the repetition rate. On the other hand, the mirror film scanners of prior art (that is, galvano scanners or other scanners of similar oscillating type) have operational cycles where stopping, accelerating and decelerating the mirror at the turning point and even stopping it for a moment give rise to certain problems and affect the usefulness of such mirrors for scanning purposes and have a particular impact on the scanning width. If an attempt is made to scale up the output rate by increasing the repetition rate, the acceleration and deceleration phases will either result in a narrow scanned area or uneven distribution of radiation, and thus also of the plasma, on the target as the radiation hits the target via a mirror that is decelerating and/or accelerating.

If an attempt is made to increase the coating/thin film production speed simply by increasing the pulse repetition rate, the above scanners of prior art will direct the pulses in an uncontrollable manner to overlapping spots on the target even when low pulse frequencies in the kHz range are used.

The same problem also applies to nanosecond range lasers, but the problems are even more serious because the pulses are of high energy and long duration. This is why even a single pulse in the nanosecond range will cause severe, noticeable erosion in the target material.

With prior art techniques, the target may not only wear out unevenly but it may also easily fragment, thus having a deteriorating effect on the quality of plasma. This is why a surface coated using such techniques will also suffer from problems attributable to plasma. The surface may have fragments or the plasma may be unevenly distributed, causing such divisions on the surface that may be problematic in conjunction with applications requiring high accuracy but not necessarily so in conjunction with paint or pigment applications where the adverse effects remain below application-specific detection limits. The current methods only use the target once so that the same target surface cannot be re-used. Attempts have been made to solve the problem by using only a virgin target surface, or by appropriately moving the target and/or the beam spot in relation to each other.

In machining-type applications, waste or excess materials containing fragments can also result in an uneven (and therefore defective) cutting line, such as in case of drilling holes related to flow control. The surfaces may even have an uneven appearance due to released fragments which is not acceptable in the manufacture of certain semiconductors, for example.

The oscillating movement of mirror film scanners also causes inertial forces that load the structure, even in cases where the mirror is supported on bearings. Such inertial forces may gradually loosen the mirror fixtures, in particular if the mirror is used close to its maximum specifications, and this may result in the settings changing gradually over a long period of time which could be evident in uneven product quality repeatability. Due to the need to stop and change direction, such mirror film scanners also have very limited scanning widths available for ablation and plasma production. The effective production cycle is short in relation to the overall duration of the production cycle even though the operation would be slow in any case. From the point of view of increasing production, a system deploying mirror film scanners is inevitably slow with respect to the plasma production rate, and it has a narrow scanning width, poor long-term stability and a high probability of encountering detrimental particle emissions in the plasma, with corresponding consequences for the machined and/or coated products where such a system was utilised.

The fibre laser technology is also associated with other problems such as the fact that large amounts of energy cannot be transmitted through the fibre without melting and/or disintegrating it or without deteriorating the transmitted beam as a result of fibre degeneration caused by the high power transmitted through it. Even a pulse power of 10 μJ can destroy the fibre if it has a minor structural defect or quality flaw. In fibre-based technology, the components most susceptible to damage are the fibre-optical connectors that are used to connect laser power sources, such as diode pumps, for example.

The shorter the pulse, the higher the power for a given energy, which means that the problem is highlighted when the laser pulse is shortened while keeping its energy content constant. The problem is particularly prominent in nanosecond lasers.

Shortening the pulse duration to the femtosecond, or even attosecond, range will make the problem almost insurmountable. For example, in a picosecond laser system with a pulse duration of 10-15 ps, the pulse energy should be 5 μJ for a 10-30 μm spot when the total power of the laser is 100 W and the repetition rate is 20 MHz. By the priority date of the current application, the author was not aware of any fibres that would withstand the said pulse.

In laser ablation, which is one important field of application for fibre lasers, it is very important to achieve the maximal and optimal pulse power and energy. In a situation where the pulse duration is 15 ps, pulse energy is 5 μJ and total power is 1000 W, the pulse power level is approximately 400 000 W (400 kW). At the time of priority date of the current application the author was not aware of anybody having succeeded in manufacturing such a fibre that would even allow passing a pulse of 200 kW with a 15 ps duration and yet keep the pulse in optimal shape.

In any event, if the objective is to avoid limiting the possibilities for producing plasma from any available material, one must be able to select the pulse power relatively freely, for example in the range of 200 kW to 80 MW.

However, the problems associated with the limitations of current fibre lasers are not attributable to fibres alone, but also to connecting separate diode-pumped lasers to each other using optical connectors for achieving the desired total power so that the resulting beam could be conveyed to the working point via a single fibre.

The suitable optical connectors must be able to withstand as much power as the optical fibre conveying the high-power pulses to the working point. Maintaining the optimal shape of the laser pulse throughout the process of transferring it is also important. Optical connectors withstanding the current power levels are very expensive to manufacture and somewhat unreliable, and they only have a short service life which means that they have to be replaced frequently.

The techniques of prior art based on laser beams and ablation have problems associated with power and quality. As an example, and particularly in the case of ablation-related scanning, the repetition rate cannot be increased to a level that would allow industrial-scale mass production with uniform, good product quality. Further, the scanners according to prior art are placed outside the vaporising device (in a vacuum chamber) so that the laser beam must travel through the optical window of the vacuum chamber which always reduces the available power to some degree.

The effective power of prior art equipment available for ablation known to the author at the time of the priority date of the current application is of the order or 10 W. This means that the repetition rate may also be limited to just 4 MHz when the cutting is effected by the laser. If an attempt is made to further increase the pulse rate, the scanners according to prior art may cause a significant part of the laser beam pulses to be uncontrollably directed to the wall structures of the laser equipment and to the ablated material in plasma form. This will have the net effect of degrading the quality of the surface formed and slowing down the production speed. Further, the radiation flux missing the target will not remain steady which may affect the structure of plasma, resulting in uneven coating when hitting the surface to be coated.

Therefore, it can also easily happen in machining applications where the target is the object and/or part to be worked that both the cutting efficiency and quality are compromised. There is also a considerable risk of fragments and splashes landing on the surfaces around the cutting point, or on surfaces intended for coating. Further, using prior art techniques makes repeated surface treatments slow, and the end result may not be of uniform quality.

The scanners according to prior art that were known to the author at the time of the priority date of the current application are only capable of scanning speeds of less than 3 m/s, and further, the scanning speed is not really constant but varies in the course of scanning. This is primarily caused by the fact that the scanners according to prior art are based on pivoting mirrors that stop when the scanned distance is completed and then turn to the opposite direction in order to repeat the scanning process. Oscillating mirrors are known in the art as such, but they have the same problems related to steady movements. Ablation techniques implemented using flat mirrors have as such been described in patent publications U.S. Pat. No. 6,372,103 and U.S. Pat. No. 6,063,455. Since the scanning speed is not constant due to the movement that accelerates, decelerates and stops, the yield of plasma produced by vaporising from the working point is different in different parts of the target, particularly at the extreme points of the scanning area, because the yield and quality of plasma are entirely dependent on the scanning speed. In a sense, one could think that as a rule, the higher the energy level and the number of pulses per time unit, the more prominent such problems are when using equipment according to prior art. During successful ablation, material is vaporised into atomic particles. But when disrupting factors are present, the target material may release or capture fragments of several micrometers in size which will naturally affect the production quality of the surface on which ablation was deployed.

Because the speeds of scanners known currently are low, increasing the pulse frequency would have the result of increasing the energy level of pulsed laser beams entering the mirror structures to such a level that the current mirror structures would meld/burn unless the laser beam is expanded by a scanner before it enters the mirror. Therefore, separate collimator lens arrangements must be added between the scanner and the ablation target.

The deciding operation-limiting property of current scanners is their light weight. This also means that their mass is small, and their capacity to absorb the energy of laser beams is equally limited. This fact also causes an increased risk of melting/burning in applications according to prior art.

Another problem with the prior art techniques is the scanning width of the laser beam. The solutions deploy linear scanning using such mirror film scanners that theoretically allow using scanning line widths up to 70 mm while in practice, the scanning width can problematically be limited to as little as 30 mm which leaves grid-like areas of uneven quality scattered unevenly on the surface. Such a small scanning width support the fact that the current laser equipment for surface treatment applications involving large and broad objects are not suitable for industrial use or are technically unfeasible.

If a situation according to prior art occurs where the laser beam is out of focus, the resulting plasma may be of rather poor quality. The released plasma may also contain fragments released from the target. At the same time, the material that is intended to be released from the target may become damaged to the extent that it is rendered useless. The situation is typical of solutions according to prior art where a target that is far too thick is used as the source of material. In order to maintain an optimal focus, the target must be moved towards the direction of the laser beam to correspond to the erosion of the target. This leaves unresolved the problem that even if it were possible to bring the target back into focus, the structure and composition of the target surface may have changed in proportion to the amount of material vaporised from it. With prior art techniques, the surface structure of thick targets changes as material is consumed. If, for example, the target is a chemical compound or mixture, the change is easy to detect.

In arrangements according to prior art, a change of focus of the laser beam during ablation in relation to the material being vaporised will immediately alter the quality of plasma as the pulse energy density on the surface of material is usually decreased, resulting in incomplete vaporisation/formation of plasma. The result is low-energy plasma and an unnecessarily large number of fragments/particles, as well as changes in surface morphology and potential changes in adhesion and coating thickness.

Attempts have been made to alleviate the problem by adjusting the focus. As the repetition rate of laser pulses in equipment of prior art is low, for example below 200 kHz, and the scanning speed is a measly 3 m/s or less, the changes will only have a slow effect on plasma intensity, whereas the equipment has time to react to the change in plasma intensity by adjusting the focus. The so-called real-time measurement system for plasma intensity can be used when a) the surface quality and its uniformity are not important, b) low scanning speeds are used.

That is why, according to the information available to the applicant at the time of the priority date of the current application, it is not possible to produce high-quality plasma using technology according to the prior art. That is also why there are many coatings that cannot be produced using prior art techniques.

The systems according to prior art require complicated systems that have to be used in them. In methods of prior art, the target is usually in the form of a thick bar or sheet. In this case, a zooming focusing lens must be used, or the target must be moved towards the laser beam as. the target is consumed. The mere practical implementation of such an arrangement is technically very expensive and difficult if not downright impossible if sufficient reliability is required and too large quality variations are to be avoided, and in that case, making accurate adjustments is almost impossible, preparing a thick target is expensive, and so on.

A US publication explains how a prior art technique can be used to direct laser pulses to the ablation target using light with S polarisation or alternatively P polarisation or circular polarisation, but not using light with random polarisation.

### SUMMARY OF THE INVENTION

The current coating methods based on laser ablation do not allow, for example, three-dimensional objects to be efficiently coated with a good quality coating. The material plasma plume created using prior art methods (typically, as discussed, 30-70 mm) increases the distance between the target to be vaporised and the substrate to be coated so that the surfaces of three-dimensional objects will be of uneven thickness or quality. The prior art methods also require, in order to have even moderate success in coating small planar objects, the use of high vacuum levels with their associated high cost, the vacuums being typically at least in the range of 10⁻⁵-10⁻⁶ mbar.

The subject of this invention is a laser ablation method for coating objects with one or more coatings in such a way that the distance between the object to be coated, or the substrate, and the material to be ablated using the laser beam, or the target, is 0.1 mm-10 mm. This invention allows the production of any planar or three-dimensional surfaces or even three-dimensional objects of good quality in an economically and industrially feasible manner.

Normally, different coating methods deploy considerably larger distances in order to achieve even coating results.

The invention now made is based on the surprising finding that planar, and particularly three-dimensional geometrical objects can be coated with excellent technical qualities (evenness, smoothness, hardness of the surface and its optical characteristics and crystal structure if applicable) and using industrially feasible production speeds in such a manner that the distance between the ablated target material and the coated substrate is kept sufficiently small, i.e., between 0.1 mm and 10 mm.

In the same context, the observation was made that the same surfaces of technically good quality can be manufactured in accordance with the invention even in low vacuum or, under certain conditions, even in a gaseous atmosphere under normal atmospheric pressure. This will naturally dramatically reduce the production costs, thanks to reduced equipment requirements (good vacuum chambers) and quicker throughput times in production. The coating of some, particularly large, objects using laser ablation has earlier been economically unfeasible because large objects would require such large and slowly pumped vacuum chambers that the production would not be economically viable. Further, certain materials, such as rock materials containing water of crystallization, prohibit the use of high vacuum as it would cause, when combined with elevated temperatures, the loss of water of crystallization, thus decomposing the rock material.

The surface production speed according to the invention is enormous compared to the production speed of prior art. When the state of the art methods allow the production of one carat (0.2 g) of diamond material in 24 hours, the current method produces, for example, four carats (0.8 g) in four hours using 20 W of laser power. It was found according to the invention that the qualitative properties of the desired material, for example diamond, can be adjusted for the current requirements.

One purpose of the invention is to present a set of equipment for surface treatment that allows solving, or at least alleviating, problems associated with the prior art techniques. Another purpose of the invention is to present a method, set of equipment and/or arrangement for coating the object to be coated more efficiently and with a higher-quality coating than is known according to the prior art techniques on the priority date of the current application. Yet another purpose is to present a three-dimensional printing unit to be implemented using such technology where the object is repeatedly coated with surface treatment equipment more effectively and with better surface quality known according to the prior art techniques on the priority date of the current application. The purposes of the invention are associated with the following goals as follows:

One of the primary goals of the invention is to create at least a new method and/or its associated equipment for solving the problem of how to produce high-quality, fine plasma by using practically any available target so that the target material does not form any fragments into the plasma, so that in other words, the plasma is pure, or, so that the said fragments, if they exist, are only present in small numbers and are smaller in size than the ablation depths from which said plasma has been produced by ablating said target.

Another goal of the invention is to create at least a new method and/or its associated equipment for solving the problem of how, by releasing high-quality plasma, to produce a fine and even cutting surface, for use in cold machining methods, so that the target material does not form any fragments into the plasma, so that in other words, the plasma is pure, or, so that said fragments, if they exist, are only present in small numbers and are smaller in size than the ablation depths from which the said plasma has been produced by ablating said target.

Another, third goal of the invention is to create at least a new method and/or its associated equipment for solving the problem of how to coat the area acting as the substrate using such high-quality plasma that contains no particle-like fragments at all, in other words, the plasma is pure, or, the said fragments, if they exist, are only present in small numbers and are smaller in size than the ablation depths from which the said plasma has been produced by ablating the said target, in other words, to coat the substrate surface by using pure plasma that can be produced practically from any material.

Another, fourth goal of the invention is to create at least a new method and/or its associated equipment for solving the problem of how to use high-quality plasma to create a coating with good adhesion properties for sticking to the substrate, in such a way that the waste of kinetic energy in particle-like fragments is reduced by limiting the occurrence of fragments or their size to less than the ablation depth. At the same time, the absence of fragments means that they do not form cool surfaces that might affect the homogeneity of the plasma plume through nucleation and condensation phenomena. Further, in accordance with the fourth goal, the radiation energy is efficiently converted to plasma energy when the area subjected to the heating effect is minimised or when, preferably, short radiation pulses are used, in other words pulses whose duration is in the picosecond range or shorter, and a certain interval between them between two successive pulses.

Another, fifth goal of the invention is to create at least a new method and/or its associated equipment for solving the problem of how to achieve an extensive scanning width with simultaneous high quality of plasma and extensive coating width even for large objects in industrial scale.

Another, sixth goal of the invention is to create at least a new method and/or its associated equipment for solving the problem of how to achieve a high repetition rate for use in industrial-scale applications in line with the above goals.

Another, seventh goal of the invention is to create at least a new method and/or its associated equipment for solving the problem of how to produce high-quality plasma for coating surfaces for the purpose of manufacturing products in line with the first to sixth goals while still saving the target material for re-use in coating stages for producing coatings/thin films of the same quality where it is required.

Yet another additional goal of the invention is to use such methods and equipment in line with the said first, second, third, fourth, and/or fifth goal for solving the problem of how to cold work and/or coat surfaces within a view of each suitable type of such products in line with the goal appropriate.

The goal of the invention is attained by producing high-quality plasma with a surface treatment apparatus based on the use of plasma, which apparatus has a turbine scanner in the radiation transmission line in accordance with an embodiment of the invention.

When using a surface treatment apparatus according to an embodiment of the invention, the removal of material from the surface being treated and/or the production of coating can be brought up to a standard that is required of a high-quality coating, even at a sufficient production speed without unnecessary limitations regarding radiation power.

Other embodiments of the invention are also presented by way of example in the dependent claims. Embodiments of the invention are combinable in suitable part.

Embodiments of the invention can be utilised in the production of products and/or coatings so that the product materials can be chosen relatively freely. Semiconductor diamond material can be produced, for example, but in a manner suitable for mass production in significant quantities, economically, in a repeatable manner and in good quality.

In a group of embodiments of the invention, surface treatment is based on laser ablation where almost any laser source can be used as the emitting radiation source for transmission on a radiation transmission line equipped with a turbine scanner. The suitable laser sources, therefore, include lasers such as CW, semiconductor lasers and pulsed laser systems with a pulse duration in the picosecond, femtosecond or attosecond range, the three latter pulse durations representing laser sources suitable for cold working methods. However, the invention does not limit the choice of radiation source as such.

### FIGURES

FIG. 1 illustrates different possible areas of application for the method in accordance with the invention

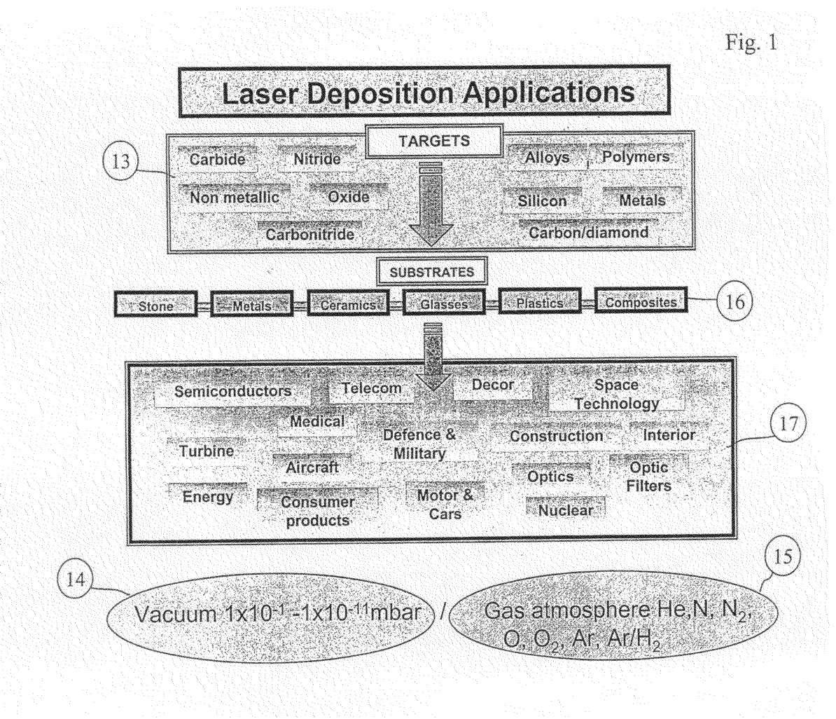

FIG. 2 illustrates a set of ablation coating equipment in accordance with one embodiment of the invention,

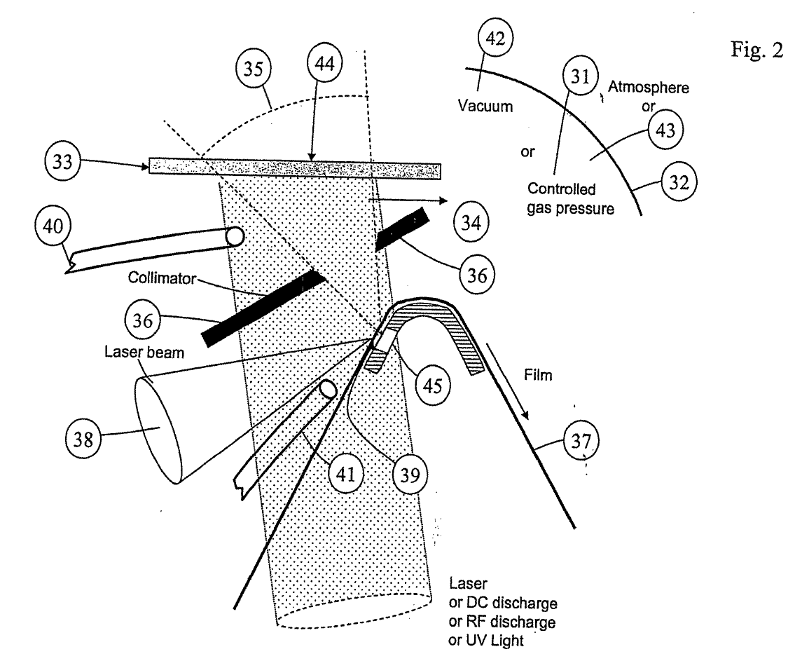

FIG. 3 illustrates a multi-layer structure on a substrate, created using equipment in accordance with an embodiment of the invention,

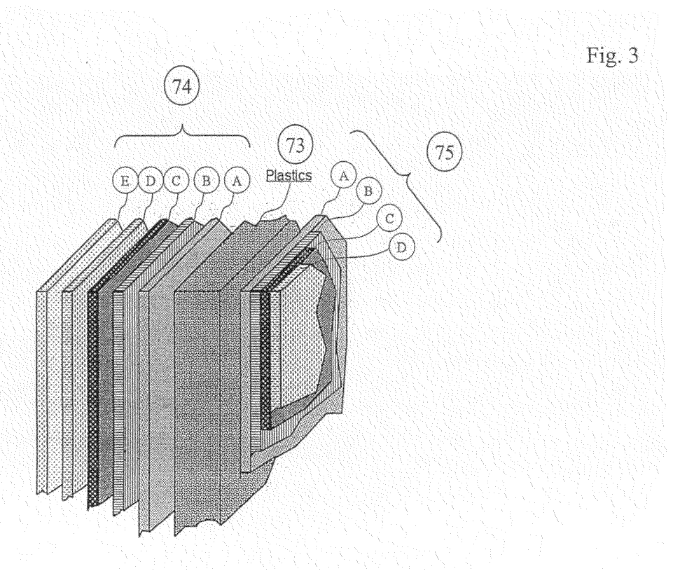

FIG. 4. illustrates one such embodiment of the invention where a monocrystalline diamond bar is produced by laser ablation in an arrangement where the carbon material to be vaporised (material blank 127) consists of pyrolytic carbon, and the distance between the target and the substrate is 4 mm,

FIG. 5. illustrates a large, three-dimensional object coated in accordance with the invention, in this case a snow scoop,

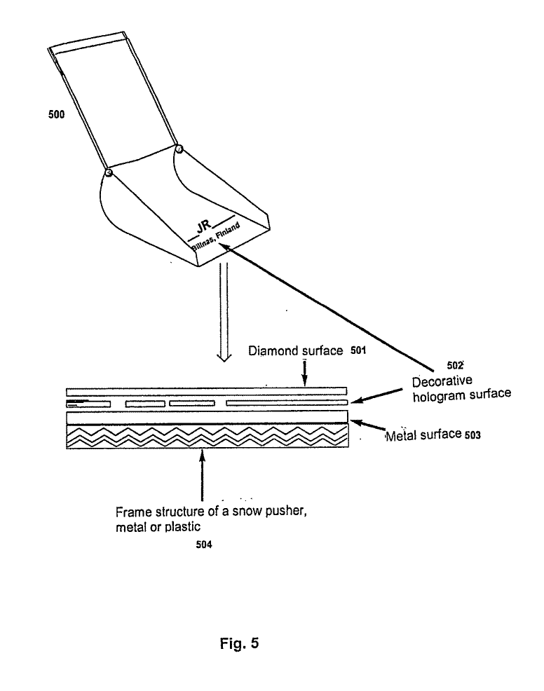

FIG. 6. illustrates a telecommunications device cover structure coated in accordance with the invention.

FIG. 7. illustrates a set of ablation coating equipment in accordance with one embodiment of the invention where the target is fed as a tape,

FIG. 8. illustrates a turbine scanner used for scanning the laser beam in certain embodiments of the invention,

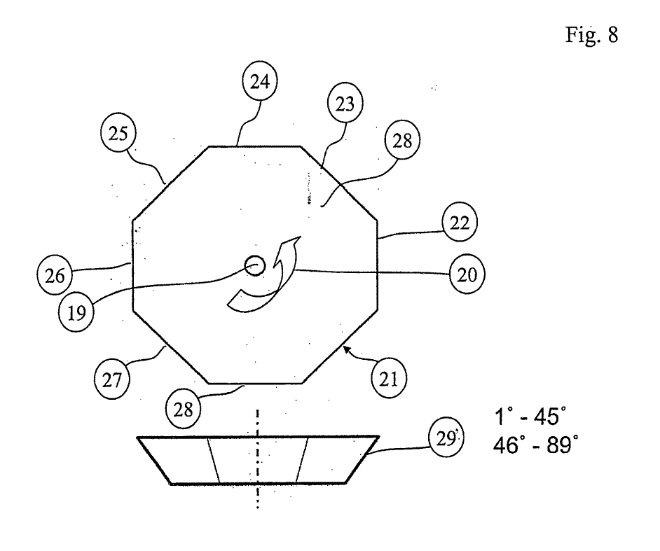

FIG. 9. illustrates the difference between hot working (microsecond and nanosecond pulse lasers, long pulses) and cold working (picosecond and femtosecond lasers, short pulses) with respect to the heat transferred to the material being ablated and the damages caused to the target material,

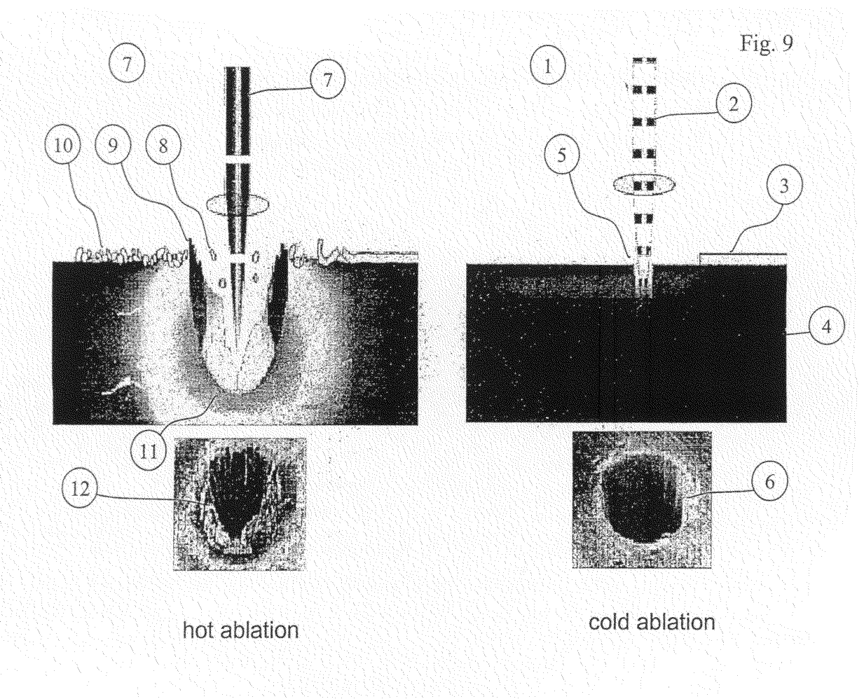

FIG. 10 illustrates certain embodiments according to the invention for coating rock products,

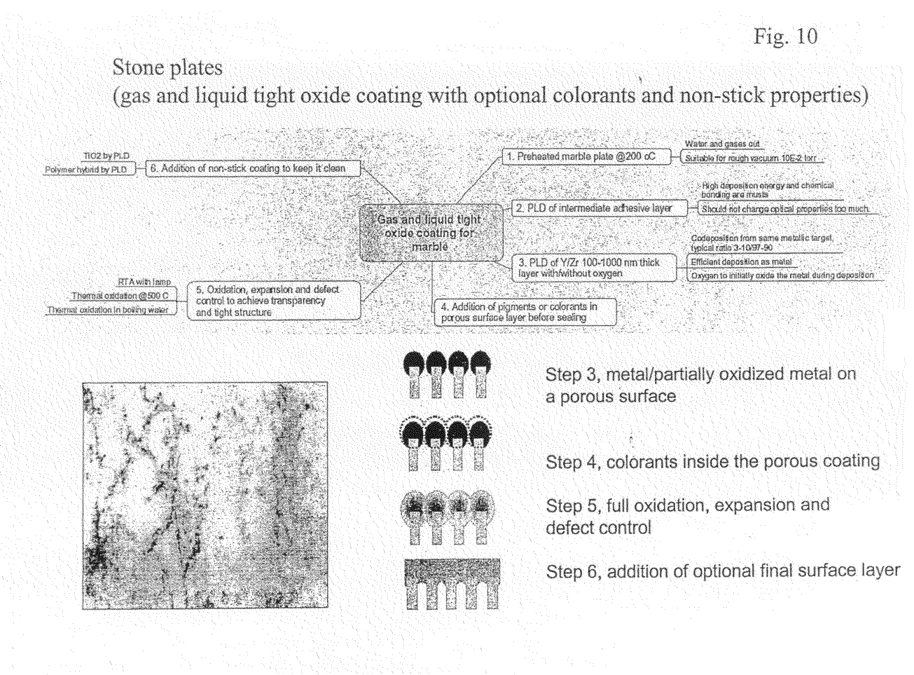

FIG. 11 illustrates certain medical instruments coated in accordance with the invention,

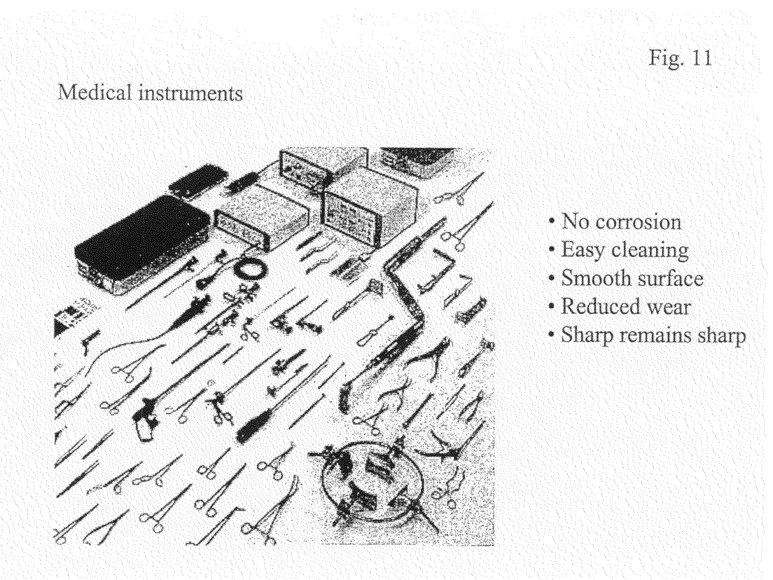

FIG. 12 illustrates certain medical products coated in accordance with the invention,

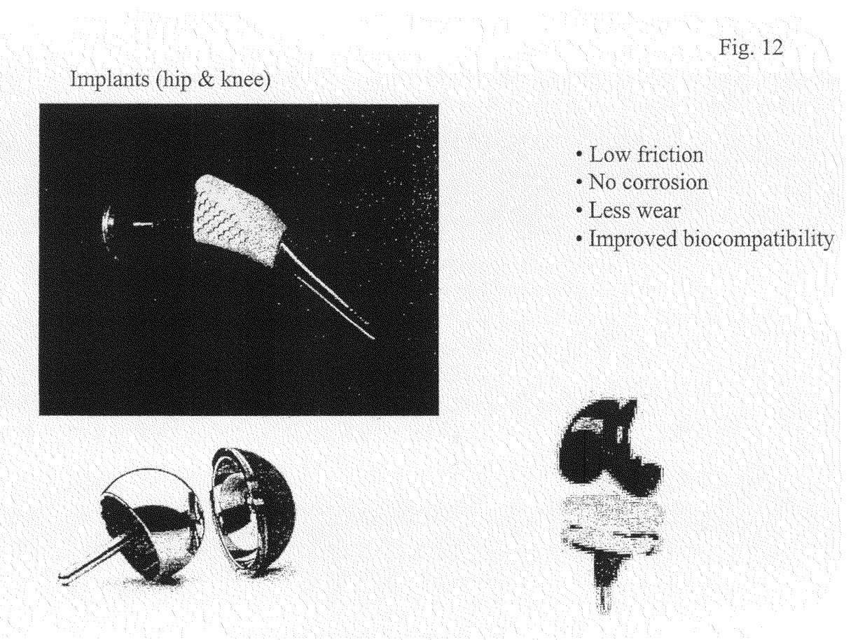

FIG. 13 illustrates certain aircraft parts coated in accordance with the invention,

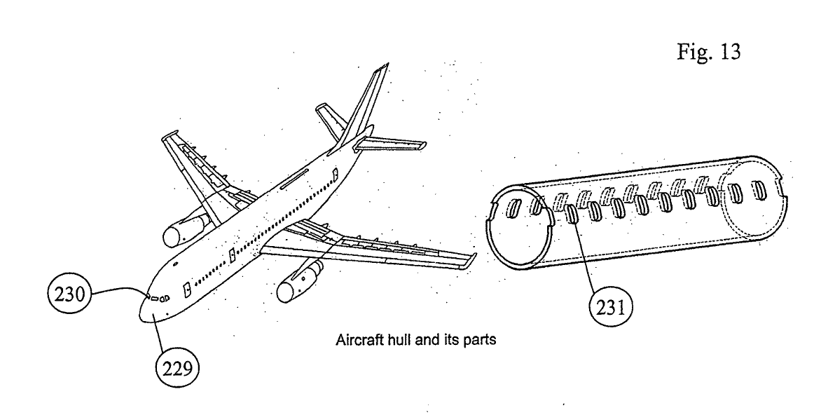

FIG. 14 illustrates certain optical products coated with aluminium oxide in accordance with the invention

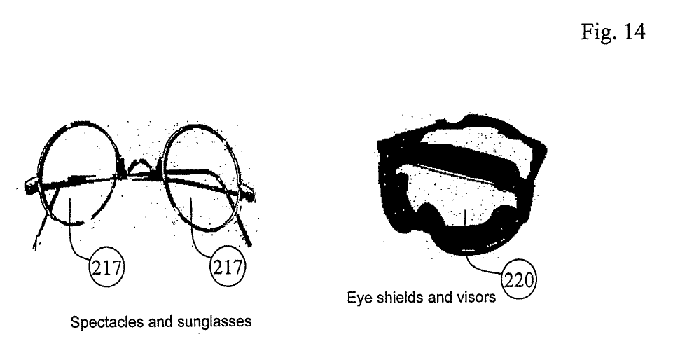

FIG. 15 illustrates certain examples of products in accordance with an embodiment of the invention that have a treated surface.

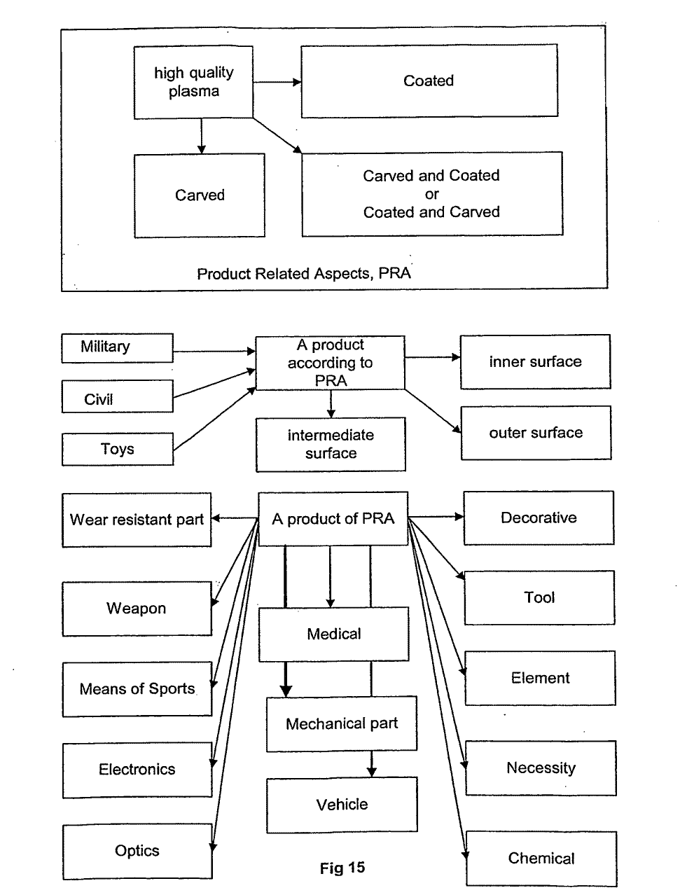

### DETAILED DESCRIPTION OF THE INVENTION

The subject of the invention is a laser ablation method for coating objects with one or more coatings in such a way that the distance between the object to be coated, or the substrate, and the material to be ablated using the laser beams, or the target, is 0.1 mm-10 mm. In one embodiment of the invention, the distance between the substrate and the target is 1 mm-8 mm, more preferably 3 mm-6 mm. The required distance depends on the substrate to be coated and the desired quality and/or technical properties of the surface.

In yet another embodiment of the invention, the distance between the target and the substrate is as small as 2 μm-0.1 mm. Using such distances, excellent surface qualities are achieved in accordance with the invention at good production speeds with, for example, pointed objects such as the points of needles and knifes. The surface hardness is also excellent. One embodiment of the invention is diamond-coated needles, knifes and blades, in particular the points of all these. Diamond can also be replaced by other hard coating materials.

In one preferable embodiment of the invention, the surface to be coated consists of material ablated from one single target.

In another preferable embodiment of the invention, the surface to be coated consists of material ablated simultaneously from several targets.

Further, in another preferable embodiment of the invention, the surface to be coated is formed by introducing reactive material into the plasma material plume formed of the ablated material, and the reactive material reacts with the ablated material of the plume of the plasma material and thus forms a compound or compounds of the coating onto the substrate.

Therefore, a molecular-level plume of plasma material is formed when the target is ablated with laser pulses.

For the sake of clarity, it must be noted that atomic plasma also refers to such at least partially ionised gas that may also contain such parts of the atom that still have electrons bonded to the nucleus by electric forces. Therefore, once ionised neon, for example, could be deemed as atomic-level plasma. Naturally, bodies of particles consisting exclusively of separate electrons and nuclei only are also considered to be plasma. Therefore, pure good plasma only contains gas, atomic-level plasma and/or plasma but not, for example, solid fragments and/or particles.

It should be noted regarding the use of pulsing in Pulsed Laser Deposition (PLD) applications that the longer the duration of the laser pulse in PLD, the lower the plasma energy level and velocity of atoms in the material vaporised from the target by the pulse hitting it. Therefore, the shorter the pulse, the higher the energy level of vaporised material and velocity of atoms in the material plume. On the other hand, this also means that the plasma obtained by vaporising material is more even and homogenous and does not contain precipitates of solid and/or liquid phase and/or condensation products such as fragments, clusters, micro particles or macro particles. In other words, the shorter the pulse and the higher the repetition rate, the better the quality of produced plasma, provided that the ablation threshold of the ablated material is exceeded.

The depth to which the heat of the laser pulse hitting the material is conducted varies considerably with different laser systems. This zone is called, inter alia, the Heat Affected Zone (HAZ). The depth of the HAZ is essentially determined by the power and duration of the laser pulse. For example, a nanosecond pulse laser system typically produces pulse powers of a few hundred millijoules or more, whereas a picosecond laser system produces pulse powers in the range of 1 . . . 10 μJ (microjoules). If the two have the same repetition rate, it is obvious that the HAZ of the 1000 times more powerful pulse produced by the nanosecond laser system is significantly larger than that of the picosecond laser. The significantly thinner ablated layer will also have a direct impact on the size of the fragments released from the surface, which is an advantage of the so-called cold ablation method. Particles in the nano size range seldom cause any major defects in the surface, mainly just pinholes in the coating when hitting the substrate. According to one embodiment of the invention, the fragments present in the solid phase (as well as in the liquid phase, if any) are removed using an electric and/or magnetic field. This can be implemented by using a collecting electric field and keeping the target under electric charge so that the fragments with less electric mobility can be directed away from the plasma plume. Magnetic filtration works in the same manner by deflecting the plasma plume, allowing the particles to be separated from the plasma.

The word surface may, in accordance with the invention, refer to a surface or 3D material. No geometrical or three-dimensional limitations are placed herein for the surface. Therefore it is not only possible to coat 3D materials in accordance with the invention, but also to produce them.

Coating substrates according to the invention allows forming smooth, pinhole free surfaces on the entire object.

According to the invention, the substrate can, for example, be composed of metal, metal compound, glass, stone, ceramic material, synthetic polymer, semi-synthetic polymer, naturally occurring polymer, composite material, inorganic or organic monomer or oligomer material, or a combination of one or more of the above substrates.

Similarly, the target can be composed of metal, metal compound, glass, stone, ceramic material, synthetic polymer, semi-synthetic polymer, naturally occurring polymer, composite material, inorganic or organic monomer or oligomer material, or a combination of one or more of the above targets.

Here, a semi-synthetic compound refers to, for example, modified naturally occurring polymers or composites containing these.

In other words, the invention is not limited to a certain substrate or target.

According to the invention, metal can be coated, for example, with another metal, metal compound, glass, stone, ceramic material, synthetic polymer, semi-synthetic polymer, naturally occurring polymer, composite material, inorganic or organic monomer or oligomer material, or a combination of one or more of the above substrates.

A metal compound can be coated, for example, with metal, another metal compound, glass, stone, ceramic material, synthetic polymer, semi-synthetic polymer, naturally occurring polymer, composite material, inorganic or organic monomer or oligomer material, or a combination of one or more of the above substrates.

Glass can be coated, for example, with metal, metal compound, another glass material, stone, ceramic material, synthetic polymer, semi-synthetic polymer, naturally occurring polymer, composite material, inorganic or organic monomer or oligomer material, or a combination of one or more of the above substrates.

Stone can be coated, for example, with metal, metal compound, glass, another rock material, ceramic material, synthetic polymer, semi-synthetic polymer, naturally occurring polymer, composite material, inorganic or organic monomer or oligomer material, or a combination of one or more of the above substrates.

Ceramics can be coated, for example, with metal, metal compound, glass, stone, another ceramic material, synthetic polymer, semi-synthetic polymer, naturally occurring polymer, composite material, inorganic or organic monomer or oligomer material, or a combination of one or more of the above substrates.

Synthetic polymer can be coated, for example, with metal, metal compound, glass, stone, ceramic material, another synthetic polymer, semi-synthetic polymer, composite material, naturally occurring polymer, inorganic or organic monomer or oligomer material, or a combination of one or more of the above substrates.

Further, semi-synthetic polymer can in accordance with the invention be coated, for example, with metal, metal compound, glass, stone, ceramic material, synthetic polymer, another semi-synthetic polymer, naturally occurring polymer, composite material, inorganic or organic monomer or oligomer material, or a combination of one or more of the above substrates.

Further, naturally occurring polymer can in accordance with the invention be coated with, for example, metal, metal compound, glass, stone, ceramic material, synthetic polymer, semi-synthetic polymer, another naturally occurring polymer, composite material, inorganic or organic monomer or oligomer material, or a combination of one or more of the above substrates.

Further, composite material can in accordance with the invention be coated with, for example, metal, metal compound, glass, stone, ceramic material, synthetic polymer, semi-synthetic polymer, naturally occurring polymer, another composite material, inorganic or organic monomer or oligomer material, or a combination of one or more of the above substrates.

Paper and cardboard can also be coated with all the above compounds.

One definition of composite materials is in the publication Polymer Science Dictionary (Alger, M. S. M, Elsewier Applied Science, 1990, p. 81) that defines composite material as follows: “A solid material consisting of a combination of two or more simple (or monolithic) materials where the individual components retain their separate identities. A composite material displays different properties than its individual component materials; the use of the attribute composite often refers to improved physical properties since the principal technological goal is to create materials with properties that are superior to those of the component materials. Composite materials also have a heterogeneous structure consisting of two or more phases based on the composite component. The phases can be continuous, or one or more phases may be dispersed phases inside a continuous matrix”.

It is also possible to produce, in accordance with the invention, besides totally new compounds, also composite materials where two or more materials are used to construct the composite material at the molecular level. In one embodiment of the invention, surfaces or 3D structures are produced from, for example, polysiloxane and diamond, in another embodiment of the invention, surfaces or 3D structures are produced from, for example, polysiloxane and carbon nitride (carbonitride). According to the invention, the relative quantities of the two or more components of the composite material can be freely chosen.

Still further, inorganic monomer or oligomer material can in accordance with the invention be coated with, for example, metal, metal compound, glass, stone, ceramic material, synthetic polymer, semi-synthetic polymer, naturally occurring polymer, composite material, another inorganic or organic monomer or oligomer material, or a combination of one or more of the above substrates.

Still further, organic monomer or oligomer material can in accordance with the invention be coated with, for example, metal, metal compound, glass, stone, ceramic material, synthetic polymer, semi-synthetic polymer, naturally occurring polymer, composite material, inorganic or another organic monomer or oligomer material, or a combination of one or more of the above substrates.

The combinations of all the above substrates can in accordance with the invention also be coated with a combination of one or more of the above substrates.

According one embodiment of the invention, the ablated material can be used for 3D printing (3-dimensional). 3D printing according to prior art techniques known at the time of the priority date of the current application (for example the brands JP-System 5 of Scroff Development Inc., Ballistic Particle Manufacturing of BPM Technology Inc., the Model Maker of Solidscape Inc., Multi Jet Modelling of 3D Systems Inc. and Z402 System of Z Corporation) utilises materials with a relatively modest mechanical durability. Since the equipment according to the invention is capable of high efficiency, i.e. a rapid layer creation rate in a relatively inexpensive manner, the ablated material can, when using e.g. carbon either in graphite or diamond form, be directed in line with the inkjet printer principle, for example, to layers that correspond to the printed object slice by slice. Thus, sufficiently durable structures can be produced using carbon, for example. However, the intention is not to limit the embodiment of the invention to diamond material only; other materials can be used based on the choice of ablated material. Thus, for example, equipment according to an embodiment of the invention can be used to produce hollow or solid objects from almost any suitable material, for example diamond or carbonitride.

Therefore, the famous sculpture of David, for example, could be first printed slice by slice, composed of diamond layers, after which any edges between the slices could be smoothed using ablation. The statue could be given a suitable tone of colour, even for each layer separately by doping/alloying the diamond material. Thus, almost any 3D-object could be printed directly, such as a tool, spare part or similar object, a part of a display, the shell structure of a PDA or another object, such as a mobile phone, or its part.

According to a preferable embodiment of the invention, the coated surface is formed so that the surface contains less than one pinhole per mm², preferably less than one pinhole per cm² and most preferably no pinholes at all on the coated area. Here, the word pinhole means either a hole protruding through the entire coating, or a hole protruding essentially through the coating. The presence of pinholes will substantially degrade the quality and service life of the coating. The subject of the invention also covers a product produced thus according to the method.

According to another embodiment of the invention, the coated surface is formed so that the first 50% of the surface is formed without any particles with a diameter exceeding 1000 nm being formed on the formed surface, preferably without the size of these particles exceeding 100 nm, and most preferably without the size of these particles exceeding 30 nm. Such particles considerably impair the quality and service life of the coating. Such particles form channels for corrosion in the coating. The subject of the invention also covers a product produced thus according to the method.

According to yet another preferable embodiment of the invention, the object to be coated, i.e. the substrate, is coated by ablating the target using a pulsed cold working laser in such a manner that the maximum roughness of the surface formed on the coated object is ±100 nm measured across an area of one square micrometer using atomic force microscopy (AFM). More preferably, the maximum roughness of the surface is less than 25 nm and most preferably less than 10 nm. The subject of the invention also covers a product produced thus according to the method.

In the coating method according to the invention, laser ablation is carried out using a pulse laser. In one particularly preferable embodiment of the invention, the laser equipment used for ablation is a cold working laser, such as a picosecond laser. In another preferable embodiment of the invention, the laser equipment is a femtosecond laser, and yet in another preferable embodiment, it is an attosecond laser.

In the method according to the invention, the power of the cold working laser is preferably at least 10 W, more preferably at least 20 W and most preferably at least 50 W. No upper limit is set here for the power of laser equipment.

In the method according to the invention, a surface (of the desired colour or transparent) of high-quality, sufficiently durable for the application and having suitable optical characteristics can be achieved by coating the substrate using laser ablation in a rough vacuum or even in a gaseous atmosphere under normal atmospheric pressure.

Coating can be done at room temperature or close to room temperature, such as by having the substrate at approximately 60° C. or by considerably increasing the substrate temperature (>100° C.).

This is particularly advantageous when coating large objects (extensive substrate surface), such as rock, metal, composite and various polymer sheets for use by the construction industry. With current coating methods of prior art, taking such objects to a sufficiently high vacuum is, besides being very expensive, also very slow and therefore dramatically increases the throughput times of the coating process. With many applications, such as when coating porous materials (rock etc.) high vacuum is impossible to achieve. If heating is also involved, most types of rock will shed their crystal water which will naturally alter the structure of this rock material and impair or destroy its usefulness for the intended application.

If coating can be carried out under normal atmospheric pressure, or in low vacuum close to it, it will therefore have an impact on both the quality and economy of the operation. In certain applications, it allows the production of products that were previously impossible to manufacture.

Many rock products can, for example, be coated in accordance with the invention with aluminium oxide in order to produce a durable surface. Besides gases, such a surface will also prevent moisture and thus, for example, the formation of rock-disintegrating fungi or ice inside or on the surface of the rock material. According to the invention, the rock material can be either coated directly with aluminium oxide or, for example, with metallic aluminium after which the formed aluminium surface can be oxidised using a multitude of methods, such as RTA+light, thermal oxidation (500° C.) or thermal oxidation in boiling water. If a quantity of a certain element, such as zirconium, is added to the aluminium, the oxidising metal surface expands even more effectively than with pure aluminium and forms a tight oxide surface that spreads to all cavities in the rock. The surface also becomes transparent. According to the invention, the rock material can also be dyed to a certain colour by adding pigments or colouring agents to the surface before final formation of the surface through oxidation. Such a surface giving colour to the rock product can be produced according to the invention using laser ablation. The aluminium oxide surface can according to the invention be replaced by any other hard surface, such as a diamond surface, carbon nitride surface, another rock surface or some other oxide surface. In one embodiment of the invention, a self-cleaning surface is deposited as the top coating of a rock product.

If the aluminium oxide surface has a monolithic crystalline structure, it is commonly called a sapphire surface.

Such a self-cleaning surface can, for example, be made of titanium or zinc oxide. According to the invention, the substrate can be coated either directly with the preferred oxide or by vaporising the preferred metal in a periphery containing oxygen. The thickness of the surface according to the invention is preferably 10 nm-150 nm, more preferably 15 nm-100 nm and most preferably 20 nm-50 nm.

If a UV protection coating is required on the substrate, the previous photocatalytic surface can be further coated with a layer of aluminium.

In another embodiment of the invention, the laser ablation is carried out in a vacuum of 10⁻¹-10⁻¹² atm.

If the coating is carried out in a vacuum, the coating or manufacture of the 3D object according to the invention is carried out preferably under a pressure of 10⁻³-10⁻⁹ atm. and most preferably under a pressure of 10⁻⁴-10⁻⁸ atm.

If a higher vacuum is used, this will be beneficial in one embodiment of the invention particularly when forming surfaces of monocrystalline material, such as monocrystalline diamond, aluminium oxide or silicon. The monocrystalline diamond or silicon materials produced in accordance with the invention are useful, for example, as semiconductors, and in case of diamonds, also as jewellery, as parts of laser equipment (light bars of diode pumps, lens solutions, fibres), as extremely durable surfaces in applications requiring such surfaces, etc.

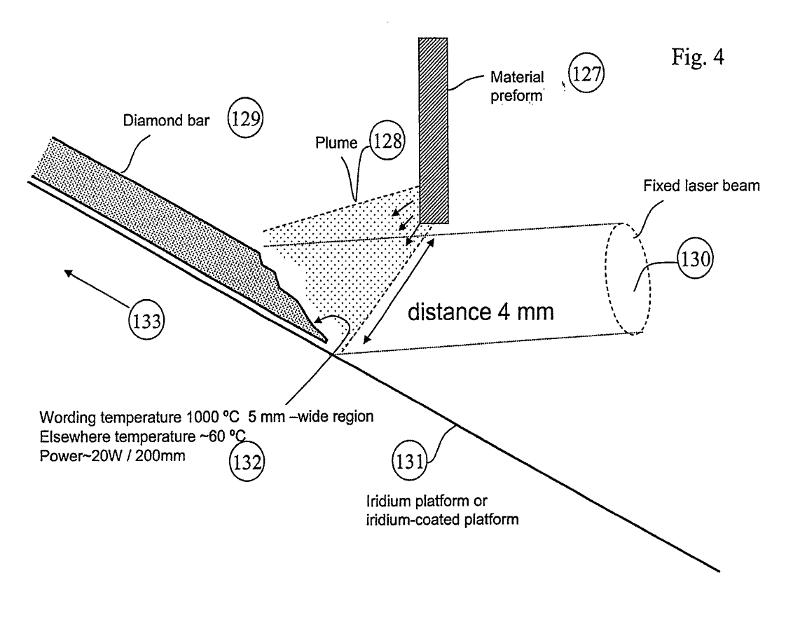

Semiconductor diamond can according to the invention be grown for example on an iridium substrate (FIG. 4), and semiconductor silicon can be grown, for example, directly on plastic or paper. If the silicon layer is thin enough, such as for example 5-15 μm, such a semiconductor can be bent, and it can be further used for example for manufacturing flexible electronics. Both diamond-based and silicon-based semiconductor materials can be cut to the desired shape, preferably using a picosecond laser and more preferably using a picosecond laser equipped with a turbine scanner. The diamond and silicon semiconductor materials manufactured according to the invention can be doped with suitable elements and combined, for example, to achieve the desired conductive properties.

in another embodiment according to the invention, one or more diamond surfaces are formed on top of the substrate. In such a diamond surface, the number of sp3 bonds is preferably very high, and unlike in the case of prior art diamond-like carbon (DLC) surfaces, the produced surface is extremely hard and scratch-resistant at all surface thicknesses in accordance with the invention. The diamond surface is preferably transparent. It also withstands high temperatures unlike, for example, the poor quality DLC of prior art that at a thickness of 1 mm is black in colour and only withstands temperatures up to 200° C. The diamond surface produced according to the invention is preferably produced using a hydrogen-free carbon source. Preferably, the carbon source is sintered carbon and most preferably pyrolytic carbon vitreous carbon.

According to the invention, pyrolytic carbon is a particularly preferable target when monocrystalline diamond material is produced, for example, for MEMS applications.

If a DLC surface of more modest quality is to be produced, that can also be done in accordance with the invention quickly and at a low cost.

If a coloured diamond surface is required, the diamond surface to be formed can be coloured by vaporising, in addition to the carbon, an element or compound producing the desired colour.

A diamond surface produced according to the invention will not only prevent the mechanical wear and tear of the underlying surfaces but also chemical attacks. The diamond surface prevents for example the oxidation of metals and the resulting impairment of their decorative or other function. The diamond surface also protects underlying surfaces against acids and alkalis.

In one preferable embodiment of the method according to the invention, the target is ablated with a laser beam so that material is all the time essentially vaporised in a spot of the target that has not been previously ablated.

This can be achieved by moving the target so that a fresh surface is always being ablated. In current methods of prior art, the target blank is usually in the form of a thick bar or sheet. They require the use of a zoom focusing lens, or the target blank must be moved in relation to the laser beam as it is consumed. The mere attempt to implement this is very difficult and expensive if at all possible with sufficient reliability, and still the quality varies a lot so that accurate control is almost impossible, producing a thick blank is expensive, etc.

Since there are limitations to the technique of controlling the laser beam, due to, inter alia, the scanners of prior art, this cannot be done without disruptions, particularly when the pulse frequency of the laser equipment is increased. If attempts are made to further increase the pulse rate to 4 MHz or above, the scanners according to prior art will cause a significant part of the laser beam pulses to be uncontrollably directed not only to the wall structures of the laser equipment but also to ablated material in plasma form. This has the net effect of degrading the quality of surface formed of the ablated material and slowing down the rate at which it is produced, as well as the effect that the flux of radiation hitting the target varies too much which can be evident in the structure of the plasma formed and result in an uneven coating surface. If all or part of the laser beam hits a surface that has already been ablated, the distance between the target and the substrate will change with respect to these pulses. When the pulses hitting the target meet earlier ablated spots of the target, different pulses will release different amounts of material so that particles of several microns in size are ablated from the target. When hitting the substrate, such particles will considerably impair the quality of the formed surface and consequently also the properties of the product.

In one embodiment of the invention, the target material is a prior art target material in rotary motion as described in publication U.S. Pat. No. 6,372,103. In another embodiment according to the invention, the target material is a tile-like target sheet that is also commercially available.

In one preferable embodiment of the invention, the target material is fed as a film/tape.

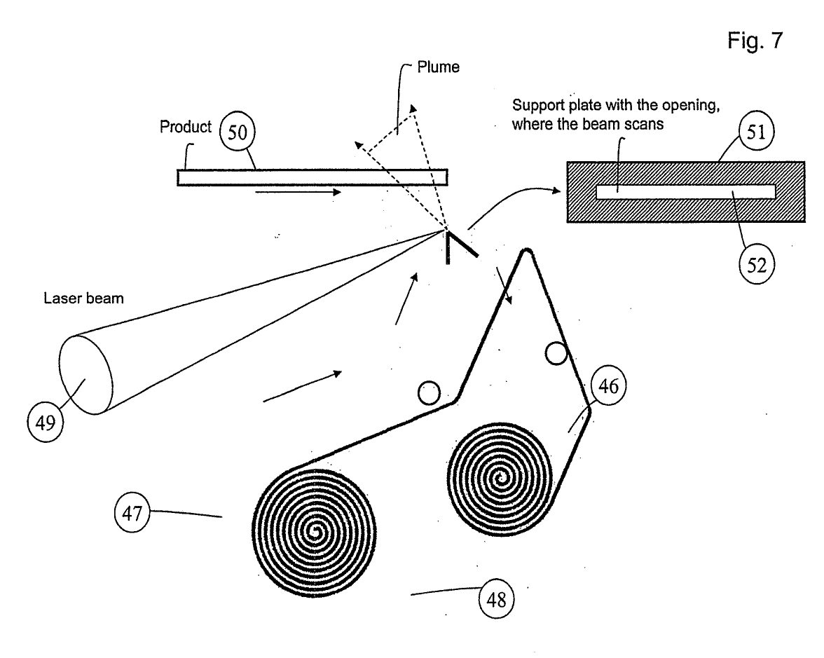

In one such preferable embodiment, the film/foil is in roll form, for example, as illustrated in FIG. 7. When the film has first been vaporised from beginning to end at the width of one laser beam fan, the tape/foil is moved by a sufficient amount to one side, for example, so that a totally new path can be formed. This can be continued until the whole width of the foil/film has been used up. The key advantage of this system is naturally the fact that the vaporising result remains constant and of top quality because the source material remains constant.

Another embodiment of the invention, based on the foil/tape (46) in FIG. 7 being a) thinner than, b) of the same thickness as or c) thicker than the depth of focus of the laser beam. Regarding case c), the part of the material that exceeds the depth of focus of the laser beam is collected on a separate roll (48). The thickness of the tape/foil can, for example, be 5 μm-5 mm, preferably 20 μm-1 mm and most preferably 50 μm-200 μm.

In one particularly preferable embodiment of the invention, the distance between the target and the substrate is kept essentially constant throughout the entire ablation process.

In a coating method according to yet another embodiment of the invention, no adjustment mechanism is required for the laser beam which means that the foil/film vaporising system according to the embodiment of the invention does not require a focus adjustment step as such. The mechanism as such is not required as the virgin surface of the film feed acts as the target because the foil/film remains constantly adjusted to focus. Of the film, only the part of the material corresponding to the depth of focus of the laser beam (FIG. 17) is utilised. Thus, a smooth coating result is achieved, and no focusing unit is required during the coating process.

Because the target materials are expensive and only the virgin surface of the target material is preferably used, it is also industrially preferable to use as thin targets as possible. Target materials in tape form are naturally considerably less expensive than the current target materials, and also more readily available due to less complicated and more economical manufacturing methods.

In another preferable embodiment of the invention, sheet feed is applied. Here, a new target in sheet form is fed for coating each object. This method of feeding is well suited, for example, for ceramic sheets of aluminium oxide that are nowadays routinely manufactured as thin and small sheets with a smooth surface. The manufacture of large targets is usually difficult and expensive.

Scanning width is one of the problems with prior art solutions. They have utilised linear scanning using a mirror film scanner; one might think that this theoretically allows a nominal scanning line width of some 70 mm, but in practice, the scanning width can problematically be limited to as little as 30 mm which means that the edges of the scanned area may be of uneven quality and/or different from the areas in the middle. Such small scanning widths also mean that the use of currently available laser equipment for industrial-scale coating applications of large, wide objects is economically or technically unfeasible.

In one preferable embodiment of the invention, the laser beam is directed at the target through a turbine scanner.

The turbine scanner solves power transmission problems associated with earlier flat mirror scanners in such a way that the target material can be vaporised using a sufficiently high pulse power, allowing plasma of good and even quality and consequently surfaces and 3D structures of good quality to be produced. The turbine scanner also enables larger scanning widths, and consequently the coating of larger surface areas with one single set of laser equipment. This means that the working speed is good and the formed surface is of even quality. In one preferable embodiment of the method according to the invention, the width of scanning the target can be 10 mm-700 mm, preferably 100 mm-400 mm and most preferably 150 mm-300 mm. Of course, it must be smaller in small-size applications. The invention must not be limited to one laser source alone. According to one embodiment of the invention, the substrate is kept stationary in a plasma material plume vaporised from one or several targets. According to one more preferable embodiment of the invention, the substrate is moved in a plasma material plume vaporised from one or several targets by laser ablation. If coating is carried out in vacuum or in an atmosphere of reactive gas, coating is preferably carried out in a separate vacuum chamber.

The invention allows coating the object in such a way that the maximum roughness of the surface formed on the coated object is ±100 nm. In one preferable embodiment of the invention, the maximum roughness of the surface formed on the coated object is ±25 nm, and in an even more preferable embodiment of the invention, the maximum roughness of the surface formed on the coated object is ∓2 nm.

The smoothness of the surface to be formed can be adjusted according to the actual requirements and the required function.

The thickness of the surfaces to be formed have not been limited in the method according to the invention. The objects can be coated according to the invention from 1 nm upwards up to very thick surfaces or even 3D structures.

The distance between the object to be coated, the substrate, and the material to be ablated, the target, is, according to prior art, 30 mm-70 mm, preferably 30 mm-50 mm.

The method according to the invention, then, allows surfaces and/or 3D materials having different functions to be produced. Such surfaces include, for example, extremely hard and scratch-resistant surfaces and 3D materials (scratch-free surfaces) in various glass and plastic products (lenses, spectacles, sunglasses, screen covers, windows of buildings and vehicles, laboratory, art and household glassware), where particularly preferable optical coating materials include MgF₂, SiO₂, TiO₂, Al₂O₃, and particularly preferable hard coating materials include various metal oxides, carbides and nitrides and, of course, diamond coatings; various metal products and their surfaces, such as the casing structures of telecommunications devices, metal sheets for roof cladding, boards for interior decoration or building, battens and window sashes; dish-washing sinks, water taps, ovens, metal coins, jewellery, tools and their parts; engines of cars and other vehicles and their parts, metal cladding and painted metal surfaces of cars and other vehicles; objects with a metal surface used in ships, boats and aeroplanes, aviation turbines and internal combustion engines; bearings; forks, knives and spoons; scissors, knives, rotary blades, saws and metal-clad cutters of all kinds, screws and nuts; metallic process equipment used in the chemical industry processes, such as metal-clad reactors, pumps, distillation columns, tanks and frame structures; oil, gas and chemical pipes and various valves and control units; parts and drill bits of oil exploration equipment; water pipes; weapons and their parts, bullets and cartridges; metal nozzles subject to wear and tear, such as paper-making machine parts subject to wear and tear, for example the parts of coating paste application equipment; snow scoops, shovels/spades and metal structures in children's playground appliances; roadside rail structures, traffic signs and posts; metal cans and vessels; surgical instruments, artificial joints and implants and instruments; cameras and video cameras and metal parts in electronic equipment susceptible to oxidation or other wear and tear and spacecraft and their cladding solutions capable of withstanding friction and high temperatures.

Further, products manufactured in accordance with the invention may include surfaces and 3D materials that withstand corrosive chemical compounds, semiconductor materials, LED materials, pigments that change colour depending on the viewing angle and surfaces built out of them, the earlier mentioned parts of laser equipment and diode pumps, such as beam expanders and diode pump light bars, precious stone materials for jewelery purposes, surfaces of medical products and medical products of three-dimensional form, self-cleaning surfaces, various products for the construction industry, such as the earlier mentioned pollution and/or moisture resistant and self-cleaning (when required) rock and ceramic materials (coated rock products and products on which a stone surface has been formed), dyed rock products, such as, according to one embodiment of the invention, marble dyed green and self-cleaning sandstone.

Further, products manufactured in accordance with the invention may include AR (anti-reflective) surfaces, for example in various lens and screen shield solutions, coatings providing UV protection and UV active surfaces used in cleaning water, solutions or air. As discussed, the thickness of the surface to be formed can be adjusted. Therefore, the thickness of a diamond or carbon nitride surface formed in accordance with the invention can for example be 1 nm-3,000 nm. In addition, a very even diamond surface can be produced. Thus, the maximum roughness of the formed diamond surface can be of the order of ±25 nm, preferably it is ±10 nm and in certain very demanding applications where low friction is required, it can be adjusted to the ±2 nm level. A diamond surface according to the invention will therefore not only prevent the mechanical wear and tear of the underlying surfaces but also chemical attacks. The diamond surface prevents, for example, the oxidation of metals and the resulting impairment of their decorative or other function. The diamond surface also protects the surfaces below against acids and alkalis. A diamond surface according to the invention will not only prevent the mechanical wear and tear of the underlying surfaces but also chemical attacks. The diamond surface prevents, for example, the oxidation of metals and the resulting impairment of their decorative or other function. The diamond surface also protects the underlying surfaces against acids and alkalis. Decorative metal surfaces are sought in certain applications. Certain particularly decorative metals or metal compounds to be utilised as target in accordance with the invention are for example gold, silver, chromium, platinum, tantalum, titanium, copper, zinc, aluminium, iron, steel, zinc black, ruthenium black, ruthenium, cobalt, vanadium, titanium nitride, titanium aluminium nitride, titanium carbon nitride, zirconium nitride, chromium nitride, titanium silicon carbide and chromium carbide. The said materials can of course be used to achieve other properties as well, such as wear-resistant surfaces or surfaces protecting against oxidation or other chemical reactions.

Metal compounds worth mentioning in this context include metal oxides, nitrides, halides and carbides, but the list of metal compounds is not limited to these.

The various oxide surfaces produced in accordance with the invention include, for example, aluminium oxide, titanium oxide, chromium oxide, zirconium oxide, tin oxide, tantalum oxide, etc., as well as composite combinations with each other or with, for example, metals, diamond, carbides or nitrides. The said materials can also be produced in accordance with the invention from metals by using an atmosphere of reactive gas.

### EXAMPLES

The following section describes a method and product according to the invention without, however, limiting the invention to the examples presented. The surfaces were produces using both the 10 W picosecond laser X-lase manufactured by Corelase Oy and the 20 W-80 W picosecond laser X-lase manufactured by Corelase, (USPLD). Pulse energy refers to the pulse energy directed at an area of one square cm that is focused on the desired area by means of optics. A wavelength of 1064 nm was used. The temperatures of the surfaces to be coated ranged from room temperature to 200° C. The temperature of the target material was adjusted for different products in the range of room temperature −700° C. The target materials used for coating included oxides, metals and various carbon-based materials. When coating was done in oxygen gas phase, the pressure of oxygen ranged from 10⁻⁴ to 10⁻¹ mbar. The low-power laser utilised a conventional flat mirror scanner, or galvano scanner. Later, coatings were carried out using a scanner rotating about its axis, or a turbine scanner. The turbine scanner allowed the scanning speed to be adjusted; the scanning speed of the beam directed at the target material was adjusted in the range of 1 m/s-350 m/s. The successful use of the galvano scanner required smaller pulse frequencies, typically below 1 MHz. Instead, good-quality coatings could be produced with the turbine scanner even when higher repetition rates were used, such as 1 MHz-30 MHz. The produced coatings were inspected using AFM-, ESEM, FTIR as well as Raman and confocal microscopes. The optical properties (transmission) and certain electronic properties, such as resistivity, were also tested. The size of spot used varied in the range of 20-80 μm.

All the investigated surfaces were pinhole-free. The roughness, or smoothness, of surfaces was measured across an area of 1 μm² using AFM equipment.

### Example 1

This example involved coating marble with a diamond coating (from sintered carbon). The laser equipment had the following performance parameters: repetition rate 4 MHz, pulse energy 5 μJ, pulse duration 20 ps, distance between the target and the substrate 4 mm, and vacuum level 10⁻⁶ atm. The produced diamond surface was inspected using AFM (Atomic Force Microscope) equipment. The thickness of the diamond surface was approximately 500 nm and maximum roughness ±10 nm. No microparticles could be seen on the surface.

### Example 2

This example involved coating aluminium foil with a diamond coating (from sintered carbon). The laser equipment had the following performance parameters: repetition rate 4 MHz, pulse energy 5 μJ, pulse duration 20 ps, distance between the target and the substrate 4 mm, and vacuum level 10⁻⁵ atm. The aluminium foil was coloured sky blue in the process. The produced diamond surface was inspected using AFM (Atomic Force Microscope) equipment. The thickness of the diamond surface was approximately 200 nm and maximum roughness ±8 nm. No microparticles could be seen on the surface.

### Example 3

This example involved coating a silicon wafer, a piece of silicon dioxide, a polycarbonate sheet and mylar film with a diamond coating (from pyrolytic carbon). The laser equipment had the following performance parameters: repetition rate 4 MHz, pulse energy 5 μJ, pulse duration 20 ps, distance between the target and the substrate 8 mm, and vacuum level 10⁻⁵ atm. The produced diamond surface was inspected using AFM (Atomic Force Microscope) equipment. The thickness of the diamond surface was approximately 150 nm and maximum roughness ±20 nm. No micro- or nanoparticles were visible on the surface.

### Example 4

This example involved coating a piece of silicon dioxide with a diamond coating. The laser equipment had the following performance parameters: repetition rate 2 MHz, pulse energy 10 μJ, pulse duration 15 ps, distance between the target and the substrate 2 mm, and vacuum level 10⁻³ atm. The produced diamond surface was inspected using AFM (Atomic Force Microscope) equipment. The thickness of the diamond surface was approximately 50 nm and maximum roughness ±4 nm. No microparticles could be seen on the surface formed. The surface had excellent roughness properties, and the maximum size of nanoparticles was 20 nm.

### Example 5

This example involved coating a piece copper sheet with copper oxide. The laser equipment had the following performance parameters: repetition rate 4 MHz, pulse energy 5 μJ, pulse duration 17 ps, distance between the target and the substrate 10 mm, and vacuum level 10⁻¹ atm. A copper oxide surface of even quality was produced. The thickness of the surface produced was approximately 5 μm.

### Example 6

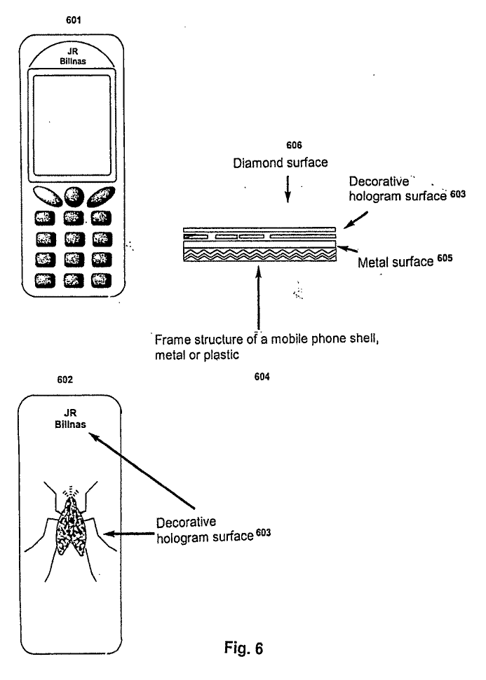

Example 6 involves a decorative snow scoop with a diamond coating produced using laser ablation (FIG. 6). Thanks to the diamond coating, the snow scoop is very durable and scratch-resistant. In addition, the hydrophobic properties of the diamond surface, and particularly its minimal (nano-range) roughness reduce friction, thus reducing the energy required for clearing snow, making it easier.

The base material of the snow scoop may be plastic or metal, for example. In the snow scoop according to the example, a one-micrometer thick layer of chromium was deposited on the aluminium base material using electrolysis. Alternatively, this can be done using laser ablation according to the invention. On a plastic surface, metal coating is easiest to deposit using laser ablation (cold ablation). The used metal, metal alloy or metal compound as well as surface thickness can be freely chosen, allowing unique snow scoops to be produced. Forming a metal surface particularly using laser ablation allows extremely thin metal surfaces with a desirable base colour to be economically produced. The diamond coating covering all surfaces will now prevent the oxidation or mechanical wear of metal surfaces. The unique features can be increased by holographic surfaces so that images or text specified by the customer can be produced on the surface. In addition to mechanical engraving, the holographic surface can also be very efficiently produced using laser engraving that allows the engraving to be made through the required surface accurately, quickly and economically. The good quality of the holographic surface is improved by the smoothness of the underlying metal surface, produced using laser ablation. The surfaces illustrated in the figure are in reality physically attached to each other, but they are shown separate in the figure for illustration purposes.

### Example 7

This example involved coating marble with an aluminium oxide coating. The surface was formed by direct ablation of aluminium oxide, and the laser equipment had the following performance parameters: repetition rate 4 MHz, pulse energy 4 μJ, pulse duration 10 ps, distance between the target and the substrate 3 mm, and vacuum level 10⁻⁶ atm. The produced aluminium oxide surface was inspected using AFM (Atomic Force Microscope) equipment. The thickness of the aluminium oxide surface was approximately 500 nm and maximum roughness ±5 nm. No micro- or nanoparticles could be seen on the surface.

### Example 8

This example involved coating marble with an aluminium oxide coating. The surface was formed by direct ablation of aluminium oxide, and the laser equipment had the following performance parameters: repetition rate 4 MHz, pulse energy 4 μJ, pulse duration 10 ps, distance between the target and the substrate 3 mm, and vacuum level 0. The produced aluminium oxide surface was inspected using AFM (Atomic Force Microscope) equipment. The thickness of the aluminium oxide surface was approximately 5 nm and maximum roughness ±10 nm. Nanoparticles were visible on the surface.

### Example 9

This example involved coating plastic spectacle frames having a base lacquer with an aluminium oxide coating. The surface was formed by direct ablation of aluminium oxide, and the laser equipment had the following performance parameters: repetition rate 4 MHz, pulse energy 4 μJ, pulse duration 20 ps, distance between the target and the substrate 3 mm, and vacuum level 10⁻⁶ atm. The produced aluminium oxide surface was inspected using AFM (Atomic Force Microscope) equipment. The thickness of the aluminium oxide surface was approximately 300 nm and maximum roughness ±2 nm. No micro- or nanoparticles could be seen on the surface.

### Example 10

This example involved coating a piece of granite with an aluminium oxide coating. The surface was formed by direct ablation of aluminium oxide, and the laser equipment had the following performance parameters: repetition rate 4 MHz, pulse energy 4 μJ, pulse duration 10 ps, distance between the target and the substrate 9 mm, and vacuum level 10⁻³ atm. The produced aluminium oxide surface was inspected using AFM (Atomic Force Microscope) equipment. The thickness of the sapphire surface was approximately 1 nm and maximum roughness ±9 nm. No significant micro- or nanoparticles could be seen on the surface.

### Example 11

This example involved coating a plastic mobile phone case, first with aluminium and then with an aluminium oxide coating. The aluminium oxide surface was formed by direct ablation of aluminium oxide, and the laser equipment had the following performance parameters: repetition rate 4 MHz, pulse energy 4 μJ, pulse duration 10 ps, distance between the target and the substrate 3 mm, and vacuum level 10⁻⁶ atm.

The produced aluminium oxide surface was inspected using AFM (Atomic Force Microscope) equipment. The thickness of the surface was approximately 300 nm and maximum roughness ±5 nm. No micro- or nanoparticles could be seen on the surface. The surface of the aluminium layer was not measured.

### Example 12

This example involved coating a piece of steel with a titanium oxide coating. The surface was formed by ablation of titanium in a helium atmosphere containing oxygen, and the laser equipment had the following performance parameters: repetition rate 20 MHz, pulse energy 4 μJ, pulse duration 10 ps, distance between the target and the substrate 1 mm, and vacuum level 10⁻² atm. The produced titanium oxide surface was inspected using AFM (Atomic Force Microscope) equipment. The thickness of the titanium oxide surface was approximately 50 nm and maximum roughness ±3 nm.

### Example 13

This example involved coating a bone screw made of stainless steel with a diamond coating (sintered carbon). The laser equipment had the following performance parameters: repetition rate 20 MHz, pulse energy 4 μJ, pulse duration 10 ps, distance between the target and the substrate 1 mm, and vacuum level 10⁻⁵ atm. The produced diamond surface was inspected using AFM (Atomic Force Microscope) equipment. The thickness of the diamond surface was approximately 100 nm and maximum roughness ±3 nm.

### Example 14

This example involved coating a bone screw made of stainless steel with a diamond coating. The surface was formed by direct ablation of titanium oxide, and the laser equipment had the following performance parameters: repetition rate 4 MHz, pulse energy 2.5 μJ, pulse duration 20 ps, distance between the target and the substrate 8 mm, and vacuum level 10⁻⁷ atm. The produced diamond surface was inspected using AFM (Atomic Force Microscope) equipment. The thickness of the diamond surface was approximately 100 nm and maximum roughness ±5 nm.

For someone skilled in the art, the facts presented in conjunction with the invention make it obvious that the object called the target at some stage of the surface treatment process could in another stage of the surface treatment process be the substrate, and vice versa, depending on whether material is ablated from it (as a target) or deposited on it (as a substrate). Therefore, it is possible, at least in theory, that the same object could act both as the target and the substrate depending on the stage of the working/coating process.

1. A laser ablation method for working and/or coating of objects by a surface or many surfaces, characterized in that, for the working and/or coating of the object, by means of using high quality plasma, the distance, between the substrate, the object to be coated, and the target, the material to be ablated by the laser beam, is 0.1 mm-10 mm.

2. A method according to claim 1, characterized in that for working and/or coating the object by using high-quality plasma, the distance between the substrate and the target is 1 mm-8 mm.

3. A method according to claim 1, characterized in that for working and/or coating the object by using high-quality plasma, the distance between the substrate and the target is 3 mm-6 mm.

4. A method according to claim 1, characterized in that for working and/or coating the object by using high-quality plasma, the substrate is of metal, metal compound, glass, stone, ceramic material, synthetic polymer, semi-synthetic polymer, paper, cardboard, naturally occurring polymer, composite material, inorganic or organic monomer or oligomer material.

5. A method according to claim 1, characterized in that for working and/or coating the object by using high-quality plasma, the target is of metal, metal compound, glass, stone, ceramic material, synthetic polymer, semi-synthetic polymer, naturally occurring polymer, composite material, inorganic or organic monomer or oligomer material.

6. A method according to claim 1, characterized in that for working and/or coating the object by using high-quality plasma, the laser ablation is carried out by using a pulse laser.

7. A method according to claim 6, characterized in that for working and/or coating the object by using high-quality plasma, the laser equipment to be used for the ablation is a cold working laser, such as a picosecond laser.

8. A method according to claim 1, characterized in that the coated surface is formed so that the surface contains less than one pinhole per mm², preferably less than one pinhole per cm² and most preferably no pinholes at all on the coated area.

9. A method according to claim 1, characterized in that the coated surface is formed so that the first 50% of the surface is formed without any particles with a diameter exceeding 1000 nm being formed on the formed surface, preferably without the size of these particles exceeding 100 rim, and most preferably without the size of these particles exceeding 30 nm.

10. A method according to claim 1, characterized in that the object to be coated, i.e. the substrate, is coated by ablating the target by using a pulsed cold working laser in such a manner that the maximum roughness of the surface to be formed on the coated object is ±100 nm measured across an area of one square micrometer using atomic force microscopy (AFM).

11. A method according to claim 1, characterized in that for working and/or coating the object by using high-quality plasma, the laser ablation is carried out under normal atmospheric pressure.

12. A method according to claim 1, characterized in that for working and/or coating the object by using high-quality plasma, the laser ablation is carried out in a vacuum of 10⁻¹-10⁻¹² atm.

13. A method according to claim 1, characterized in that the target is ablated by using a laser beam in such a manner that for working and/or coating the object by using high-quality plasma, material is essentially all the time vaporised from such an area of the target that has previously not been significantly ablated.

14. A method according to claim 13, characterized in that for working and/or coating the object by using high-quality plasma, the target is fed as sheets.

15. A method according to claim 13, characterized in that for working and/or coating the object by using high-quality plasma, the target is fed as a film/tape.

16. A method according to claim 15, characterized in that for working and/or coating the object by using high-quality plasma, the thickness of the target is 5 μm-5 mm, preferably 20 μm-1 mm and most preferably 50 μm-200 μm.

17. A method according to claim 1, characterized in that for working and/or coating the object by using high-quality plasma, the laser beam is directed at the target through a turbine scanner.

18. A method according to claim 17, characterized in that for working and/or coating the object by using high-quality plasma, the scanning width that the target is subjected to is 10 mm-800 mm, preferably 100 mm-400 mm and most preferably 150 mm-300 mm.

19. A method according to claim 1, characterized in that for working and/or coating the object by using high-quality plasma, the substrate is moved in a plasma material plume vaporised from one or several targets using laser ablation.

20. A method according to claim 1, characterized in that for working and/or coating the object by using high-quality plasma, the distance between the target and the substrate is kept essentially constant throughout the ablation process.

21. A method according to claim 1, characterized in that for working and/or coating the object by using high-quality plasma, the coated surface consists of material simultaneously ablated from several targets.

22. A method according to claim 1, characterized in that for working and/or coating the object by using high-quality plasma, the surface to be coated is formed by introducing reactive material into the plasma material plume formed out of the ablated material, so that said reactive material reacts with the ablated material of plasma material of the plume thus forming compound or compounds of the coating on the substrate.

23. A set of surface treatment equipment, characterized in that it has, for working and/or coating the object by using high-quality plasma, a turbine scanner in the radiation transmission line of the surface treatment equipment.
